(19) United States
(12) Patent Application Publication
(10) Pub. No.: US 2025/0283214 A1
(43) Pub. Date: Sep. 11, 2025

(54) FILM FORMING METHOD AND FILM FORMING APPARATUS

(71) Applicant: Tokyo Electron Limited, Tokyo (JP)

(72) Inventors: Yuki KIKUCHI, Nirasaki City (JP); Mitsuaki IWASHITA, Nirasaki City (JP); Seishin YAMADA, Tokyo (JP)

(21) Appl. No.: 19/070,912

(22) Filed: Mar. 5, 2025

(30) Foreign Application Priority Data
Mar. 7, 2024 (JP) 2024-034512
Jul. 31, 2024 (JP) 2024-124656

(51) Int. Cl. C23C 16/04; C23C 2/00; C23C 2/02; C23C 2/04; C23C 16/02; C23C 16/06; C23C 16/56

(52) U.S. Cl. CPC C23C 16/042; C23C 2/0064; C23C 2/022; C23C 2/024; C23C 2/04; C23C 16/0209; C23C 16/0227; C23C 16/045; C23C 16/06; C23C 16/56

(57) ABSTRACT

A film forming method includes, sequentially performing: preparing a substrate having a first metal film and a first insulating film formed in different regions of a surface of the substrate; forming a first self-assembled monolayer on a surface of the first metal film selectively with respect to a surface of the first insulating film; forming a first bonding film on both the surface of the first insulating film and a surface of the first self-assembled monolayer using a first molecular bonding agent; removing the first self-assembled monolayer to remove a portion of the first bonding film in contact with the surface of the first self-assembled monolayer; and forming a second metal film on the surface of a remaining portion of the first bonding film and the surface of the first metal film.

### CROSS-REFERENCE TO RELATED APPLICATIONS

This application is based upon and claims the benefit of priority from Japanese Patent Application Nos. 2024-034512 and 2024-124656, filed on Mar. 7, 2024 and Jul. 31, 2024, respectively, the entire contents of which are incorporated herein by reference.

### TECHNICAL FIELD

The present disclosure relates to a film forming method and a film forming apparatus.

### BACKGROUND

A film forming method described in Patent Document 1 includes forming a TiN film along a recess of an interlayer insulating film, and filling the recess of the interlayer insulating film with a Ru film in this order. The TiN film improves adhesion of the Ru film to the interlayer insulating film.

A bonding method described in Patent Document 2 bonds a first substrate and a second substrate using a compound. The compound has an OH group or an OH generating group, an azide group, and a triazine ring in one molecule.

### PRIOR ART DOCUMENTS

### Patent Documents

Patent Document 1: Japanese Patent Laid-open Publication No. 2022-152438

Patent Document 2: International Publication No. 2012/043631

### SUMMARY

According to one embodiment of the present disclosure, a film forming method includes, sequentially performing: preparing a substrate having a first metal film and a first insulating film formed in different regions of a surface of the substrate; forming a first self-assembled monolayer on a surface of the first metal film selectively with respect to a surface of the first insulating film; forming a first bonding film on both the surface of the first insulating film and a surface of the first self-assembled monolayer using a first molecular bonding agent; removing the first self-assembled monolayer to remove a portion of the first bonding film in contact with the surface of the first self-assembled monolayer; and forming a second metal film on the surface of a remaining portion of the first bonding film and the surface of the first metal film. The first molecular bonding agent is an organic compound having a first functional group and a second functional group in one molecule. The first functional group is more likely to bond to the first insulating film than the second functional group. The second functional group is more likely to bond to the second metal film than the first functional group.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart showing a film forming method according to a first reference example.

FIG. 2A is a cross-sectional view showing S101 in FIG. 1. FIG. 2B is a cross-sectional view showing S102 in FIG. 1. FIG. 2C is a cross-sectional view showing S103 in FIG. 1. FIG. 2D is a cross-sectional view showing S104 in FIG. 1.

FIG. 3 is a flowchart showing a film forming method according to a first embodiment.

FIG. 4A is a cross-sectional view showing S202 in FIG. 3. FIG. 4B is a cross-sectional view showing S203 in FIG. 3. FIG. 4C is a cross-sectional view showing S204 in FIG. 3. FIG. 4D is a cross-sectional view showing S205 in FIG. 3. FIG. 4E is a cross-sectional view showing S206 in FIG. 3.

FIG. 5 is a flowchart showing a film forming method according to a second reference example.

FIG. 6A is a cross-sectional view showing S101 in FIG. 5. FIG. 6B is a cross-sectional view showing S102 in FIG. 5. FIG. 6C is a cross-sectional view showing S103 in FIG. 5. FIG. 6D is a cross-sectional view showing S104 in FIG. 5. FIG. 6E is a cross-sectional view showing S105 in FIG. 5.

FIG. 7 is a flowchart showing a film forming method according to a second embodiment.

FIG. 8A is a cross-sectional view showing S202 in FIG. 7. FIG. 8B is a cross-sectional view showing S203 in FIG. 7. FIG. 8C is a cross-sectional view showing S204 in FIG. 7. FIG. 8D is a cross-sectional view showing S205 in FIG. 7. FIG. 8E is a cross-sectional view showing S206 in FIG. 7. FIG. 8F is a cross-sectional view showing S207 in FIG. 7.

FIG. 9 is a flowchart showing a film forming method according to a third reference example, and is a flowchart of a process performed following S103 in FIG. 5.

FIG. 10A is a cross-sectional view showing S111 in FIG. 9. FIG. 10B is a cross-sectional view showing S112 in FIG. 9. FIG. 10C is a cross-sectional view showing S113 in FIG. 9. FIG. 10D is a cross-sectional view showing S114 in FIG. 9.

FIG. 11 is a flowchart showing a film forming method according to a third reference example, and is a flowchart of a process performed following S205 in FIG. 7.

FIG. 12A is a cross-sectional view showing S211 in FIG. 11. FIG. 12B is a cross-sectional view showing S212 in FIG. 11. FIG. 12C is a cross-sectional view showing S213 in FIG. 11. FIG. 12D is a cross-sectional view showing S214 in FIG. 11. FIG. 12E is a cross-sectional view showing S215 in FIG. 11. FIG. 12F is a cross-sectional view showing S216 in FIG. 11.

FIG. 13 is a plan view showing a film forming apparatus according to an embodiment.

FIG. 14 is a cross-sectional view showing an example of a first processing part shown in FIG. 13.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the drawings. Throughout the drawings, the same or similar components are designated by the same reference numerals, and descriptions thereof may be omitted.

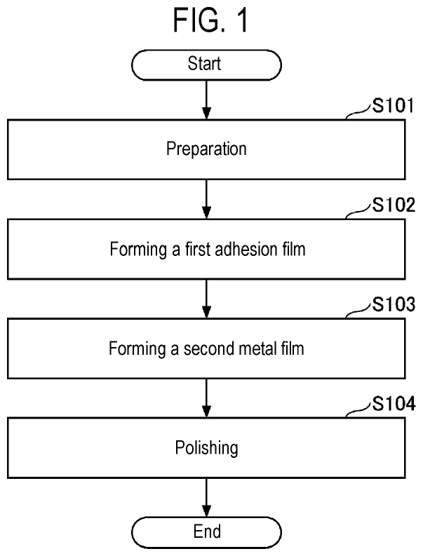

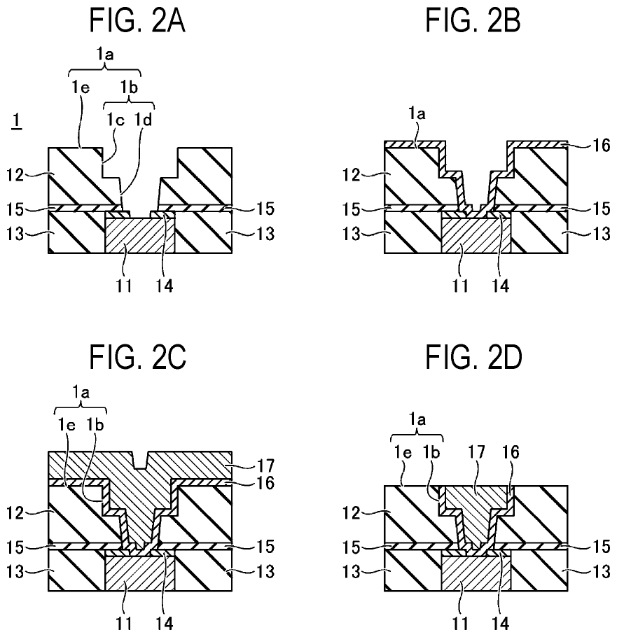

A film forming method according to a first reference example will be described with reference to FIGS. 1 and 2A to 2D. In the film forming method according to the first reference example, a metal wiring is formed by a dual damascene method. As shown in FIG. 1, the film forming method according to the first reference example includes steps S101 to S104. The film forming method may include steps other than steps S101 to S104. For example, the film forming method may include a step of cleaning a substrate surface between steps S101 and S102.

Step S101 includes preparing a substrate 1 as shown in FIG. 2A. The substrate 1 includes a semiconductor substrate or a glass substrate (not shown), and various functional films formed on the semiconductor substrate or the glass substrate. The substrate 1 includes a first metal film 11 and a first insulating film 12 in different regions of a substrate surface 1a. The first metal film 11 is, for example, a Ru film. The first metal film 11 may include Ru and may be a Ru alloy film. The first metal film 11 may be a Cu film, a Co film, a W film, or a Mo film. The first metal film 11 may be an alloy film containing at least one of Cu, Co, W, or Mo. The first insulating film 12 is, for example, an interlayer insulating film.

The interlayer insulating film is preferably a SiO film or a low dielectric constant (low-k) film having a dielectric constant lower than that of the SiO film. The low-k film is not particularly limited, but may be, for example, a SiCO film, a SiOCH film, or a SiCN film. In this regard, the SiO film means a film containing silicon (Si) and oxygen (O). The atomic ratio of the elements constituting the SiO film is not limited to a stoichiometric ratio. Similarly, the SiCO film, the SiOCH film, and the SiCN film contain respective elements, and the atomic ratio of the respective elements constituting each film is not limited to a stoichiometric ratio.

The substrate 1 has a recess 1b on the substrate surface 1a. The recess 1b has, for example, a trench 1c and a via hole 1d formed in the bottom surface of the trench 1c. The substrate 1 has a surface of a first metal film 11 on a bottom surface of the recess 1b, and a surface of a first insulating film 12 on a side surface of the recess 1b. The substrate 1 has a top surface of a protrusion 1e on the substrate surface 1a, and a recess 1b recessed from the top surface of the protrusion 1e. The substrate 1 has a surface of the first insulating film 12 on the top surface of the protrusion 1e.

The substrate 1 may further include a second insulating film 13. The second insulating film 13 is, for example, an interlayer insulating film. In a recess of the second insulating film 13, a first metal film 11 and a third adhesive film 14 are filled in this order. The third adhesive film 14 improves adhesiveness between the first metal film 11 and an etching stopper film 15 described later. The third adhesive film 14 is, for example, a TiN film or a TaN film. The atomic ratio of the elements constituting the TiN film or the TaN film is not limited to a stoichiometric ratio.

The substrate 1 may further include an etching stopper film 15. The etching stopper film 15 is formed on the second insulating film 13 and the third adhesive film 14. The etching stopper film 15 stops the etching of the first insulating film 12 for formation of the recess 1b. The etching stopper film 15 is, for example, a SiN film or a SiCN film. The atomic ratio of elements constituting the SiN film or the SiCN film is not limited to a stoichiometric ratio.

After the etching of the first insulating film 12 for forming the recess 1b is completed, a part of the etching stopper film 15 and a part of the third adhesive film 14 are removed to expose the first metal film 11 on the bottom surface of the recess 1b (see FIG. 2A). As a result, the substrate 1 may have a surface of the third adhesive film 14 and a surface of the etching stopper film 15 on the side surface of the recess 1b.

Step S102 includes forming a first adhesive film 16 as shown in FIG. 2B. The first adhesive film 16 is formed over the entire substrate surface 1a conformally with the shape of the substrate surface 1a. The first adhesive film 16 improves adhesiveness between the first insulating film 12 and a second metal film 17, which will be described later. The first adhesive film 16 is, for example, a TiN film or a TaN film. The first adhesive film 16 is formed by, for example, a CVD (Chemical Vapor Deposition) method or an ALD (Atomic Layer Deposition) method.

Step S103 includes forming a second metal film 17 as shown in FIG. 2C. The second metal film 17 is, for example, a Ru film. The second metal film 17 may include Ru and may be a Ru alloy film. The second metal film 17 may be a Cu film, a Co film, a W film, or a Mo film. The second metal film 17 may be an alloy film containing at least one of Cu, Co, W, or Mo. The second metal film 17 is formed by, for example, a PVD (Physical Vapor Deposition) method, a CVD method, or a plating method.

The second metal film 17 fills the recess 1b. The second metal film 17 contacts the first adhesive film 16 at the bottom surface of the recess 1b. The second metal film 17 also contacts the first adhesive film 16 at the side surface of the recess 1b and the top surface of the protrusion 1e. The first adhesive film 16 improves the adhesiveness between the first insulating film 12 and the second metal film 17.

Step S104 includes polishing the second metal film 17 as shown in FIG. 2D. The polishing method is, for example, CMP (Chemical Mechanical Polishing). Step S104 includes polishing the second metal film 17, and then simultaneously polishing the second metal film 17 and the first insulating film 12. A surface of the second metal film 17 and the surface of the first insulating film 12 are aligned in the same plane. The second metal film 17 filled in the first insulating film 12 may form a metal wiring.

According to the first reference example, as shown in FIG. 2D, the first adhesive film 16 remains between the second metal film 17 and the first metal film 11. The remaining first adhesive film 16 increases contact resistance between the second metal film 17 and the first metal film 11. Therefore, in the first embodiment described later, a first bonding film is used instead of the first adhesive film 16, and a first self-assembled monolayer is formed before the formation of the first bonding film. Hereinafter, the first self-assembled monolayer may be referred to as a first SAM (Self-Assembled Monolayer).

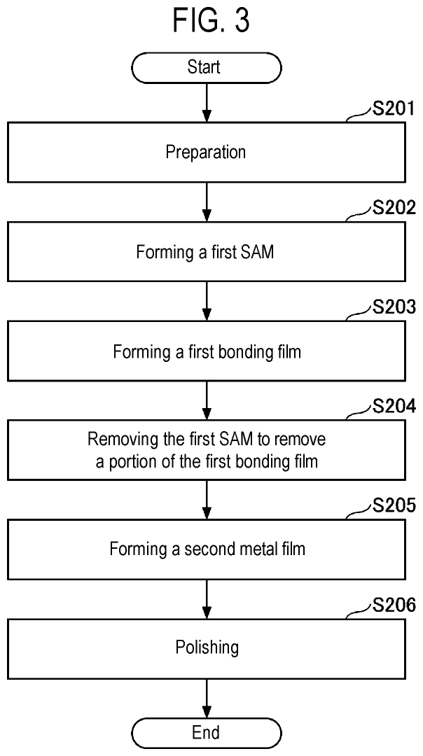

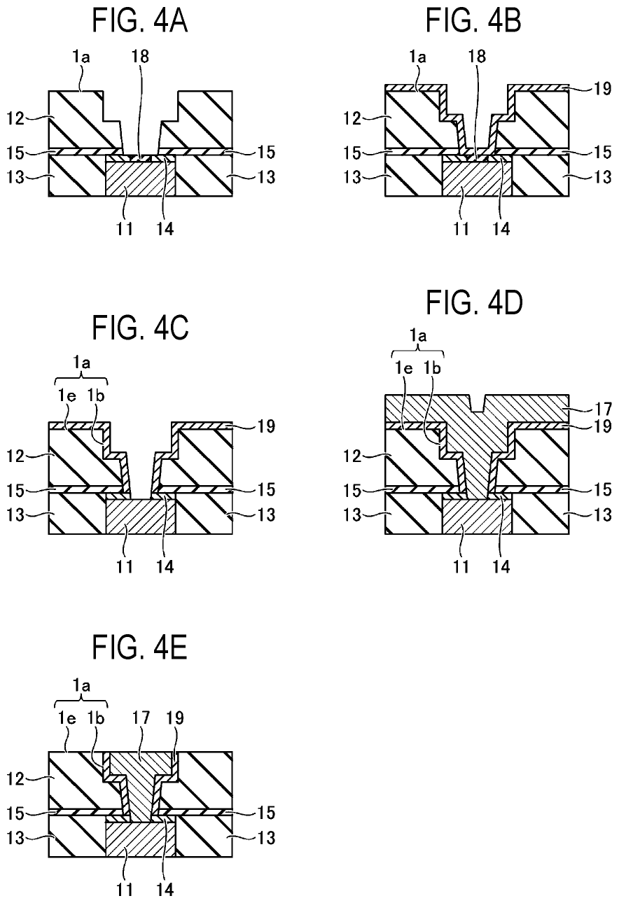

A film forming method according to a first embodiment will be described with reference to FIGS. 3 and 4A to 4E. In the film forming method according to the first embodiment, a metal wiring is formed by a dual damascene method. As shown in FIG. 3, the film forming method according to the first embodiment includes steps S201 to S206. The film forming method may include steps other than steps S201 to S206. For example, the film forming method may include a step of cleaning a substrate surface between steps S201 and S202.

Step S201 includes preparing a substrate 1. The substrate 1 to be prepared is similar to the substrate 1 prepared in S101 of the first reference example (see FIG. 2A), and therefore the illustration and description thereof will be omitted.

Step S202 includes forming a first SAM 18 as shown in FIG. 4A. The material of the first SAM 18 is, for example, an organic compound containing a thiol group. Specific examples of the thiol-based compound include CF₃(CF₂)₅CH₂CH₂SH (1H,1H,2H,2H-perfluorooctanethiol: PFOT) and CH₃(CH₂)₅SH (hexanethiol: HT).

The thiol-based compound is more likely to be chemically adsorbed onto the surface of the first metal film 11 than onto the surface of the first insulating film 12. Therefore, the first SAM 18 is formed on the surface of the first metal film 11 selectively with respect to the surface of the first insulating film 12. The first SAM 18 is hardly formed on the surface of the first insulating film 12.

The material of the first SAM 18 is not limited to the thiol-based compound. The raw material gas of the first SAM 18 may include a phosphonic acid-based compound, a carboxylic acid-based compound, or a nitro-based compound. The material of the first SAM 18 may be supplied in a liquid state dissolved in an organic solvent, or in a state of a gas vaporized by heating.

Step S203 includes forming a first bonding film 19 as shown in FIG. 4B. The first bonding film 19 is formed on both the surface of the first insulating film 12 and a surface of the first SAM 18. The first bonding film 19 may be formed over the entire substrate surface 1a conformally with a shape of the substrate surface 1a. The first bonding film 19 may also be formed on the surface of the third adhesive film 14 and the surface of the etching stopper film 15 inside the recess 1b. The material of the first bonding film 19 is a first molecular bonding agent. The first molecular bonding agent may be supplied in a liquid state dissolved in an organic solvent, or in a state of a gas vaporized by heating.

The first molecular bonding agent is an organic compound having a first functional group and a second functional group in one molecule. The first functional group is more likely to be bonded to the first insulating film 12 than the second functional group. The first functional group is not particularly limited, but may include at least one of a silanol group or a group that generates a silanol group by hydrolysis reaction. The group that generates a silanol group by hydrolysis reaction is, for example, an alkoxysilyl group. A plurality of first functional groups may be present in one molecule, and the plurality of first functional groups may be the same or different.

The second functional group is more likely to be bonded to the second metal film 17 than the first functional group. The second functional group is not particularly limited, but may include, for example, at least one of an amino group, an azide group, a mercapto group, an isocyanate group, a ureido group, or an epoxy group. A plurality of second functional groups may be present in one molecule, and the plurality of second functional groups may be the same or different.

The first molecular bonding agent preferably has a triazine between the first functional group and the second functional group. The first molecular bonding agent may contain at least one of benzene, cyclohexane, naphthalene, spiro compound, lactone, pyridine, cyclopentane, furan, or thiophene, instead of the triazine.

As shown in FIG. 4C, step S204 includes removing the first SAM 18 to remove the portion of the first bonding film 19 that contacts the surface of the first SAM 18. The remaining portion of the first bonding film 19 covers the surface of the first insulating film 12, and the surface of the first metal film 11 is exposed again at the bottom of the recess 1b.

Removing the first SAM 18 includes, for example, heating the first SAM 18. The first SAM 18 may be thermally decomposed. The heating temperature is not particularly limited as long as it is higher than a 1% weight loss temperature of the first SAM 18, and is, for example, 300 degrees C. to 450 degrees C. The 1% weight loss temperature is a temperature at which the weight of a substance decreases by 1% when the substance is heated from the room temperature at a heating rate of 10 degrees C./min in a nitrogen atmosphere. The 1% weight loss temperature is measured by a differential thermal analyzer. The holding time of the heating temperature is set according to the heating temperature, and is, for example, 1 minute to 60 minutes, preferably 1 minute to 30 minutes.

The 1% weight loss temperature of the first SAM 18 is preferably lower than the 1% weight loss temperature of the first bonding film 19. Even if the heating temperature is a low temperature at which the thermal decomposition of the first bonding film 19 hardly progresses, a portion of the first bonding film 19 may be removed. The heating temperature may be lower than the 1% weight loss temperature of the first bonding film 19.

Furthermore, removing the first SAM 18 may include supplying acetic acid to the first SAM 18. The acetic acid breaks the bond between the first SAM 18 and the first metal film 11, and removes the first SAM 18. The acetic acid breaks, for example, a sulfide bond. Therefore, supplying the acetic acid is particularly effective when the first SAM 18 is a thiol-based compound. The supply time of the acetic acid is not particularly limited, but may be, for example, 1 minute to 60 minutes, preferably 1 minute to 30 minutes.

The supply of the acetic acid to the first SAM 18 is preferably performed after the heating of the first SAM 18, but may be performed before the heating of the first SAM 18. Further, step S204 may include only one of the heating the first SAM 18 and the supplying the acetic acid to the first SAM 18.

Step S205 includes forming a second metal film 17 as shown in FIG. 4D. The second metal film 17 is, for example, a Ru film. The second metal film 17 may include Ru and may be a Ru alloy film. The second metal film 17 may be a Cu film, a Co film, a W film, or a Mo film. The second metal film 17 may also be an alloy film containing at least one of Cu, Co, W, or Mo. The second metal film 17 is formed by, for example, a CVD method or a plating method.

The second metal film 17 fills the recess 1b. The second metal film 17 contacts the first metal film 11 at the bottom surface of the recess 1b. There is no other functional film between the first metal film 11 and the second metal film 17. The second metal film 17 contacts the first bonding film 19 at the side surface of the recess 1b and at the top surface of the protrusion le. The first bonding film 19 bonds the first insulating film 12 and the second metal film 17. This makes it possible to suppress the peeling of the second metal film 17 from the first insulating film 12. The first bonding film 19 may bond the etching stopper film 15 and the second metal film 17.

Step S206 includes polishing the second metal film 17 as shown in FIG. 4E. The polishing method is, for example, CMP. Step S206 includes polishing the second metal film 17 and then simultaneously polishing the second metal film 17 and the first insulating film 12. The surface of the second metal film 17 and the surface of the first insulating film 12 are aligned in the same plane. The second metal film 17 filled in the first insulating film 12 may form a metal wiring.

According to the first embodiment, as shown in FIG. 4E, there is no other functional film between the second metal film 17 and the first metal film 11. The second metal film 17 and the first metal film 11 are in continuous contact with each other. Therefore, the contact resistance between the second metal film 17 and the first metal film 11 may be reduced. In addition, according to the first embodiment, the adhesiveness between the first insulating film 12 and the second metal film 17 may be improved by the remaining portion of the first bonding film 19.

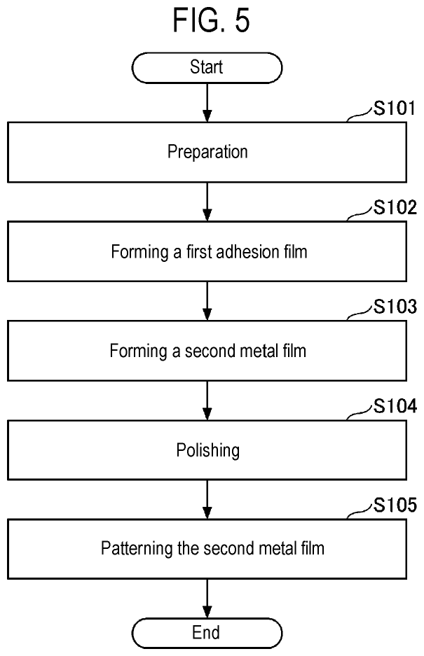

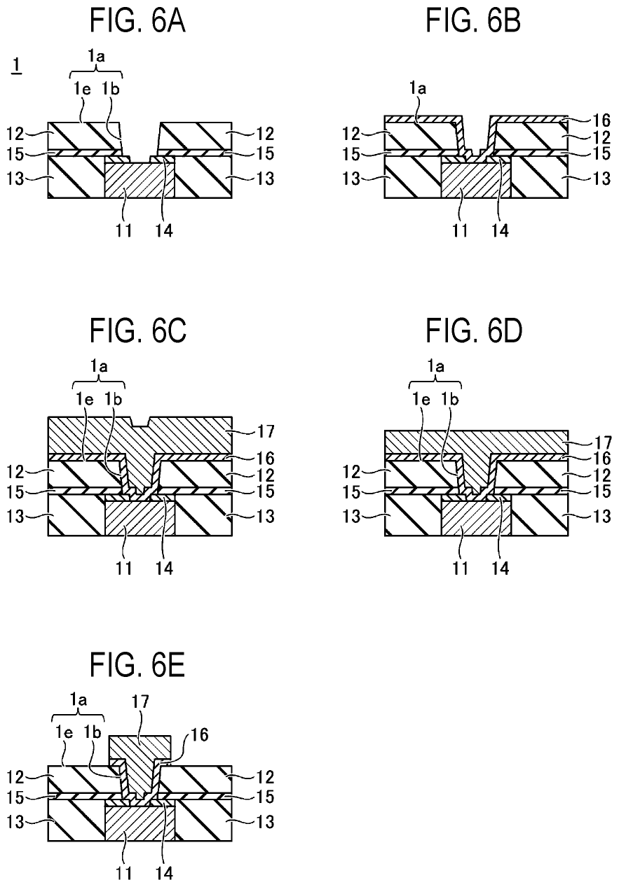

A film forming method according to a second reference example will be described with reference to FIGS. 5 and 6A to 6E. In the film forming method according to the second reference example, a metal wiring is formed by a semi-damascene method. The film forming method according to the second reference example includes steps S101 to S105 as shown in FIG. 5. The following mainly describes the differences from the first reference example.

Step S101 includes preparing a substrate 1 as shown in FIG. 6A. The substrate 1 has the recess 1b on the substrate surface 1a. The recess 1b has the via hole 1d shown in FIG. 2A, but does not have the trench 1c shown in FIG. 2B. The substrate 1 has a surface of a first metal film 11 on the bottom surface of the recess 1b, and a surface of a first insulating film 12 on the side surface of the recess 1b. The substrate 1 has a top surface of a protrusion 1e on the substrate surface 1a, and a recess 1b recessed from the top surface of the protrusion 1e. The substrate 1 has a surface of a first insulating film 12 on the top surface of the protrusion 1e.

Step S102 includes forming a first adhesive film 16 as shown in FIG. 6B. The first adhesive film 16 is formed over the entire substrate surface 1a conformally with the shape of the substrate surface 1a.

Step S103 includes forming a second metal film 17 as shown in FIG. 6C. The second metal film 17 fills the recess 1b. The second metal film 17 contacts the first adhesive film 16 at the bottom surface of the recess 1b. The second metal film 17 also contacts the first adhesive film 16 at the side surface of the recess 1b and at the top surface of the protrusion 1e. The first adhesive film 16 improves the adhesiveness between the first insulating film 12 and the second metal film 17.

Step S104 includes polishing the second metal film 17 as shown in FIG. 6D. The second metal film 17 is planarized. The second metal film 17 covers the first insulating film 12, and the surface of the first insulating film 12 is not exposed.

Step S105 includes patterning the second metal film 17 as shown in FIG. 6E. The patterning may be performed using, for example, a photolithography technique and an etching technique. The remaining second metal film 17 may form a metal wiring.

According to the second reference example, as shown in FIG. 6E, the first adhesive film 16 remains between the second metal film 17 and the first metal film 11. The remaining first adhesive film 16 increases the contact resistance between the second metal film 17 and the first metal film 11. Therefore, in a second embodiment described later, a first bonding film is used instead of the first adhesive film 16, and a first self-assembled monolayer is formed before the formation of the first bonding film.

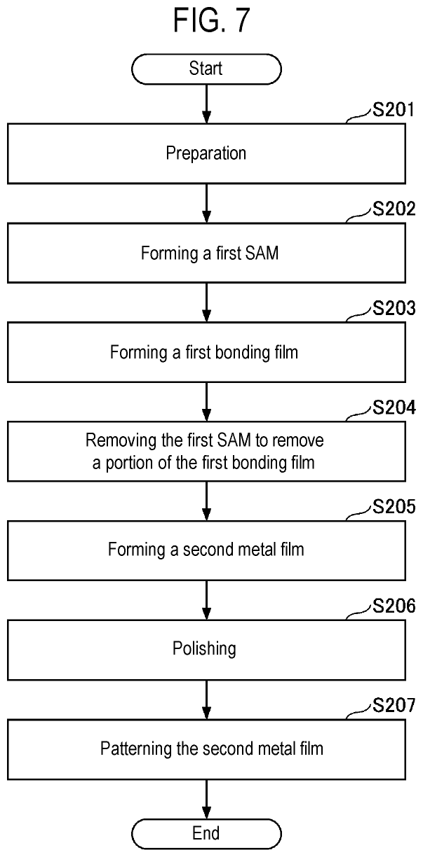

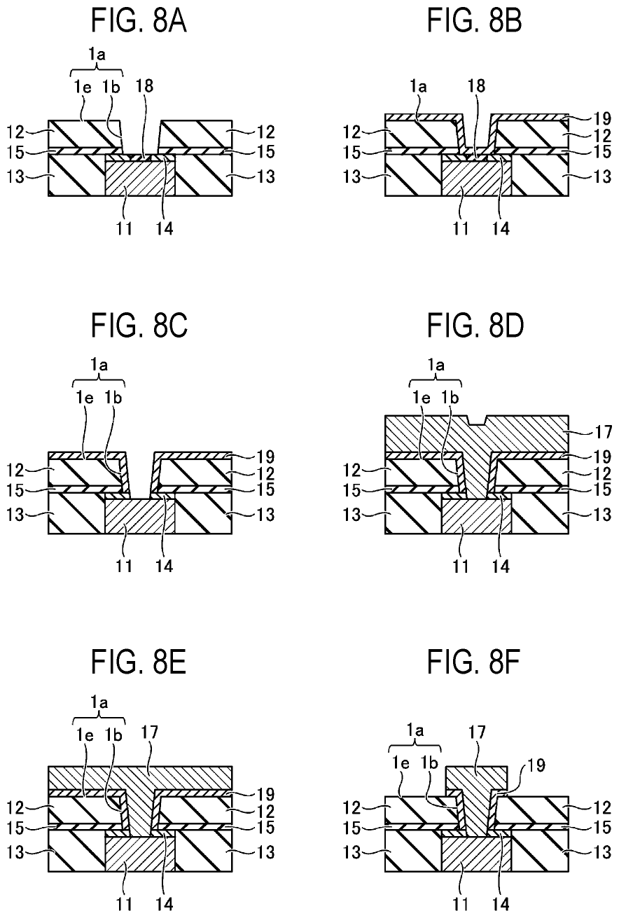

A film forming method according to a second embodiment will be described with reference to FIGS. 7 and 8A to 8F. In the film forming method according to the second embodiment, a metal wiring is formed by a semi-damascene method. The film forming method according to the second embodiment includes steps S201 to S207 as shown in FIG. 7. The following mainly describes the differences from the first embodiment.

Step S201 includes preparing a substrate 1. The substrate 1 to be prepared is similar to the substrate 1 prepared in S101 of the second reference example (see FIG. 6A), and therefore the illustration and description thereof will be omitted.

Step S202 includes forming a first SAM 18 as shown in FIG. 8A. The first SAM 18 is formed on the surface of the first metal film 11 selectively with respect to the surface of the first insulating film 12. The first SAM 18 is hardly formed on the surface of the first insulating film 12.

Step S203 includes forming a first bonding film 19 as shown in FIG. 8B. The first bonding film 19 is formed on both the surface of the first insulating film 12 and the surface of the first SAM 18. The material of the first bonding film 19 is the first molecular bonding agent.

Step S204 includes removing the first SAM 18 as shown in FIG. 8C to remove the portion of the first bonding film 19 that contacts the surface of the first SAM 18. The remaining portion of the first bonding film 19 covers the surface of the first insulating film 12, and the surface of the first metal film 11 is exposed again at the bottom of the recess 1b.

Step S205 includes forming a second metal film 17 as shown in FIG. 8D. The second metal film 17 fills the recess 1b. The second metal film 17 contacts the first metal film 11 at the bottom surface of the recess 1b. There is no other functional film between the first metal film 11 and the second metal film 17. The second metal film 17 contacts the first bonding film 19 at the side surface of the recess 1b and at the top surface of the protrusion 1e. The first bonding film 19 bonds the first insulating film 12 and the second metal film 17. This may suppress peeling of the second metal film 17 from the first insulating film 12. The first bonding film 19 may bond the etching stopper film 15 and the second metal film 17.

Step S206 includes polishing the second metal film 17 as shown in FIG. 8E. The second metal film 17 is planarized. The second metal film 17 covers the first insulating film 12, and the surface of the first insulating film 12 is not exposed.

Step S207 includes patterning the second metal film 17 as shown in FIG. 8F by using, for example, a photolithography technique and an etching technique. The remaining second metal film 17 may form a metal wiring.

According to the second embodiment, as shown in FIG. 8F, there is no other functional film between the second metal film 17 and the first metal film 11. The second metal film 17 and the first metal film 11 are in continuous contact with each other. Therefore, the contact resistance between the second metal film 17 and the first metal film 11 may be reduced. In addition, according to the second embodiment, the adhesiveness between the first insulating film 12 and the second metal film 17 may be improved by the remaining portion of the first bonding film 19.

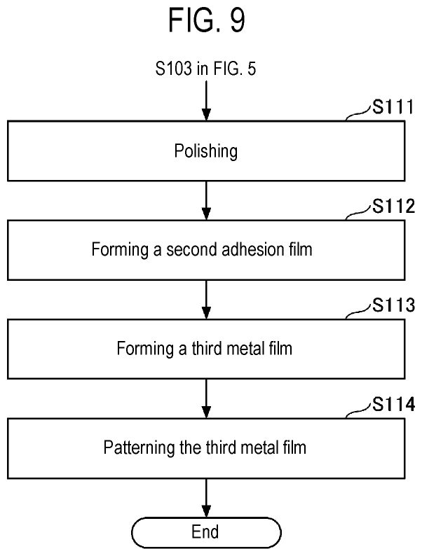

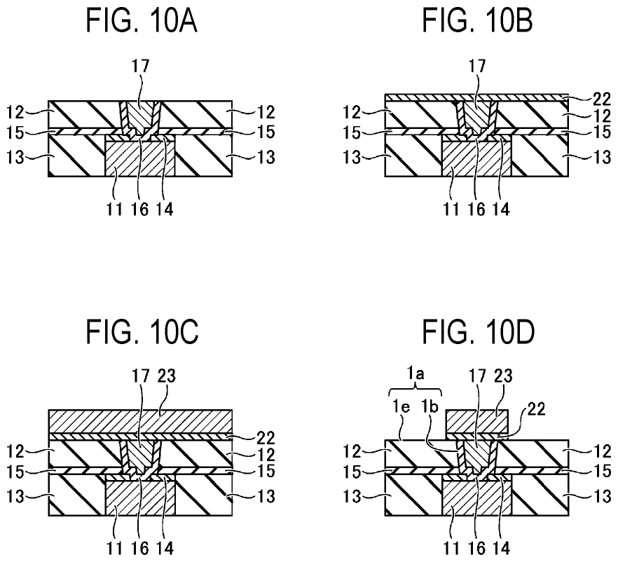

A film forming method according to a third reference example will be described with reference to FIGS. 9 and 10A to 10D. The film forming method according to the third reference example forms a metal wiring by a semi-damascene method different from that of the second reference example. As shown in FIG. 9, the film forming method according to the third reference example includes steps S111 to S114 following step S103 shown in FIG. 5. The following mainly describes the differences from the second reference example.

As shown in FIG. 10A, step S111 includes polishing the second metal film 17. Step S111 includes polishing the second metal film 17 and then simultaneously polishing the second metal film 17 and the first insulating film 12. The surface of the second metal film 17 and the surface of the first insulating film 12 are aligned in the same plane.

Step S112 includes forming a second adhesive film 22 as shown in FIG. 10B. The second adhesive film 22 is formed on both the surface of the second metal film 17 and the surface of the first insulating film 12. The second adhesive film 22 improves the adhesiveness between the first insulating film 12 and a third metal film 23 described below. The second adhesive film 22 is, for example, a TiN film or a TaN film. The second adhesive film 22 is formed by, for example, a CVD method or an ALD method.

Step S113 includes forming a third metal film 23 as shown in FIG. 10C. The third metal film 23 contacts the second adhesive film 22. The second adhesive film 22 improves adhesiveness between the first insulating film 12 and the third metal film 23. The third metal film 23 is, for example, a Ru film. The third metal film 23 may include Ru, and may be a Ru alloy film. The third metal film 23 may be a Cu film, a Co film, a W film, or a Mo film. The third metal film 23 may also be an alloy film containing at least one of Cu, Co, W, or Mo. The third metal film 23 is formed by, for example, a CVD method or a plating method.

Step S114 includes patterning the third metal film 23 as shown in FIG. 10D. The patterning may be performed using, for example, a photolithography technique and an etching technique. The remaining third metal film 23 may form a metal wiring.

According to the third reference example, as shown in FIG. 10D, the second adhesive film 22 remains between the third metal film 23 and the second metal film 17. The remaining second adhesive film 22 increases contact resistance between the third metal film 23 and the second metal film 17. Therefore, in a third embodiment described later, a second bonding film is used instead of the second adhesive film 22, and a second self-assembled monolayer is formed before the formation of the second bonding film. Hereinafter, the second self-assembled monolayer may be referred to as a second SAM (Self-Assembled Monolayer).

A film forming method according to a third embodiment will be described with reference

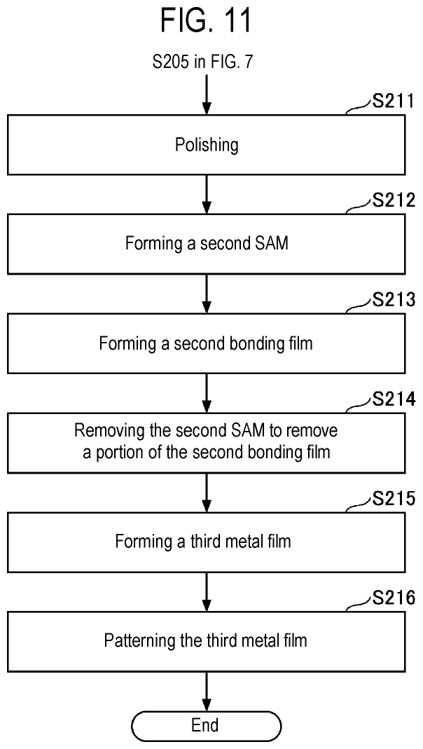

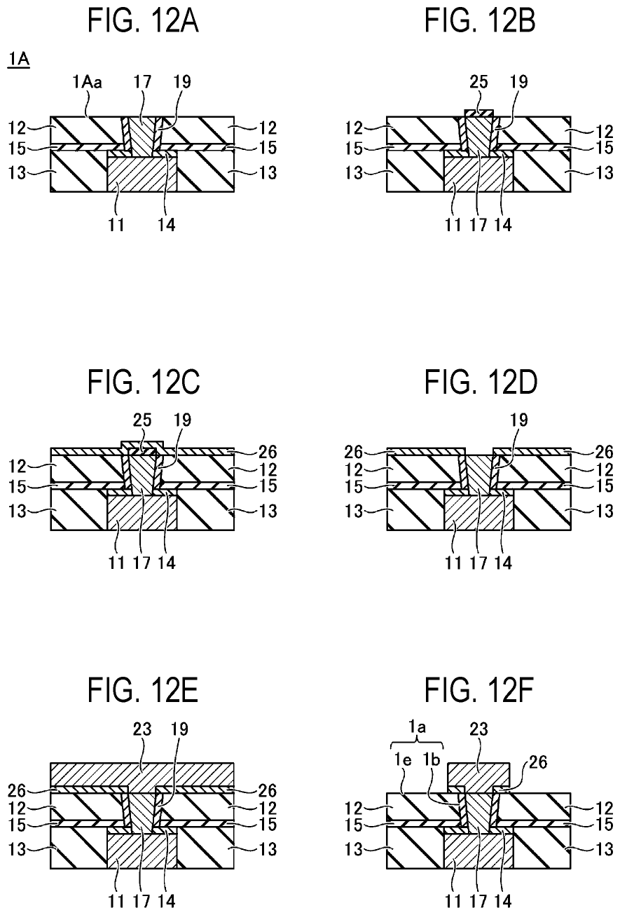

to FIGS. 11 and 12A to 12F. The film forming method according to the third embodiment forms a metal wiring by a semi-damascene method different from that of the second embodiment. As shown in FIG. 11, the film forming method according to the third embodiment includes steps S211 to S216 following step S205 shown in FIG. 7. The following mainly describes the differences from the second embodiment.

As shown in FIG. 12A, step S211 includes polishing the second metal film 17. Step S211 includes polishing the second metal film 17 and then simultaneously polishing the second metal film 17 and the first insulating film 12. The surface of the second metal film 17 and the surface of the first insulating film 12 are aligned in the same plane.

Step S212 includes forming a second SAM 25 as shown in FIG. 12B. The material of the second SAM 25 is similar to the material of the first SAM 18, and therefore the description thereof will be omitted. The second SAM 25 is formed on the surface of the second metal film 17 selectively with respect to the surface of the first insulating film 12. The second SAM 25 is hardly formed on the surface of the first insulating film 12.

Step S213 includes forming a second bonding film 26 as shown in FIG. 12C. The second bonding film 26 is formed on both the surface of the first insulating film 12 and the surface of the second SAM 25. The material of the second bonding film 26 is a second molecular bonding agent. The second molecular bonding agent may be supplied in a liquid state dissolved in an organic solvent, or in a state of a gas vaporized by heating.

The second molecular bonding agent is an organic compound having a third functional group and a fourth functional group in one molecule. The third functional group is more likely to bond to the first insulating film 12 than the fourth functional group. The third functional group is not particularly limited, but may include at least one of a silanol group or a group that generates a silanol group by hydrolysis reaction. The group that generates a silanol group by hydrolysis reaction is, for example, an alkoxysilyl group. A plurality of third functional groups may be present in one molecule, and the plurality of third functional groups may be the same or different.

The fourth functional group is more likely to bond to the third metal film 23 than the third functional group. The fourth functional group is not particularly limited, but may include, for example, at least one of an amino group, an azide group, a mercapto group, an isocyanate group, a ureido group, or an epoxy group. A plurality of fourth functional groups may be present in one molecule, and the plurality of fourth functional groups may be the same or different.

The second molecular bonding agent preferably includes a triazine between the third and fourth functional groups. The second molecular bonding agent may include at least one of benzene, cyclohexane, naphthalene, spiro compound, lactone, pyridine, cyclopentane, furan, or thiophene, instead of triazine.

Step S214 includes removing the second SAM 25 shown in FIG. 12D to remove the portion of the second bonding film 26 that contacts the surface of the second SAM 25. The remaining portion of the second bonding film 26 covers the surface of the first insulating film 12, and the surface of the second metal film 17 is exposed again.

Removing the second SAM 25 includes, for example, heating the second SAM 25. The second SAM 25 may be thermally decomposed. The heating temperature is not particularly limited as long as it is higher than a 1% weight loss temperature of the second SAM 25, and is, for example, 300 degrees C. to 450 degrees C. The holding time of the heating temperature is set according to the heating temperature, and is, for example, 1 minute to 60 minutes, preferably 1 minute to 30 minutes.

The 1% weight loss temperature of the second SAM 25 is preferably lower than the 1% weight loss temperature of the second bonding film 26. Even if the heating temperature is low enough that the thermal decomposition of the second bonding film 26 hardly progresses, a portion of the second bonding film 26 may be removed. The heating temperature may be lower than the 1% weight loss temperature of the second bonding film 26.

Further, removing the second SAM 25 may include supplying acetic acid to the second SAM 25. The acetic acid breaks the bond between the second SAM 25 and the second metal film 17, and removes the second SAM 25. The acetic acid breaks, for example, sulfide bonds. Therefore, supplying acetic acid is particularly effective when the second SAM 25 is a thiol-based compound. The supply time of acetic acid is not particularly limited, but may be, for example, 1 minute to 60 minutes, preferably 1 minute to 30 minutes.

The supply of acetic acid to the second SAM 25 is preferably performed after the heating of the second SAM 25, but may be performed before the heating of the second SAM 25. Further, step S214 may include only one of the heating the second SAM 25 and the supplying the acetic acid to the second SAM 25.

Step S215 includes forming the third metal film 23 as shown in FIG. 12E. The third metal film 23 is, for example, a Ru film. The third metal film 23 may include Ru and may be a Ru alloy film. The third metal film 23 may be a Cu film, a Co film, a W film, or a Mo film. The third metal film 23 may also be an alloy film containing at least one of Cu, Co, W, or Mo. The third metal film 23 is formed by, for example, a CVD method or a plating method.

The third metal film 23 is in contact with the second metal film 17. There is no other functional film between the second metal film 17 and the third metal film 23. In addition, the third metal film 23 is in contact with the remaining portion of the second bonding film 26. The remaining portion of the second bonding film 26 bonds the first insulating film 12 and the third metal film 23. This makes it possible to suppress the peeling of the third metal film 23 from the first insulating film 12.

Step S216 includes patterning the third metal film 23 as shown in FIG. 12F by using, for example, a photolithography technique and an etching technique. The remaining third metal film 23 may form a metal wiring.

According to the third embodiment, as shown in FIG. 12F, there is no other functional film between the third metal film 23 and the second metal film 17. The third metal film 23 and the second metal film 17 are in continuous contact with each other. Therefore, the contact resistance between the third metal film 23 and the second metal film 17 may be reduced. In addition, according to the third embodiment, the adhesiveness between the first insulating film 12 and the third metal film 23 may be improved by the remaining portion of the second bonding film 26.

The film forming method may include preparing a substrate 1A (see FIG. 12A) obtained in step S211 of the third embodiment. The substrate 1A has no recess on a substrate surface 1Aa. The substrate surface 1Aa is a planar surface on which the surface of the second metal film 17 and the surface of the first insulating film 12 are aligned.

In this case, the second metal film 17, the second SAM 25, and the second bonding film 26 may correspond to the first metal film, the first SAM, and the first bonding film recited in the claims. Accordingly, in this case, the second bonding agent, the third functional group, and the fourth functional group may correspond to the first bonding agent, the first functional group, and the second functional group recited in the claims.

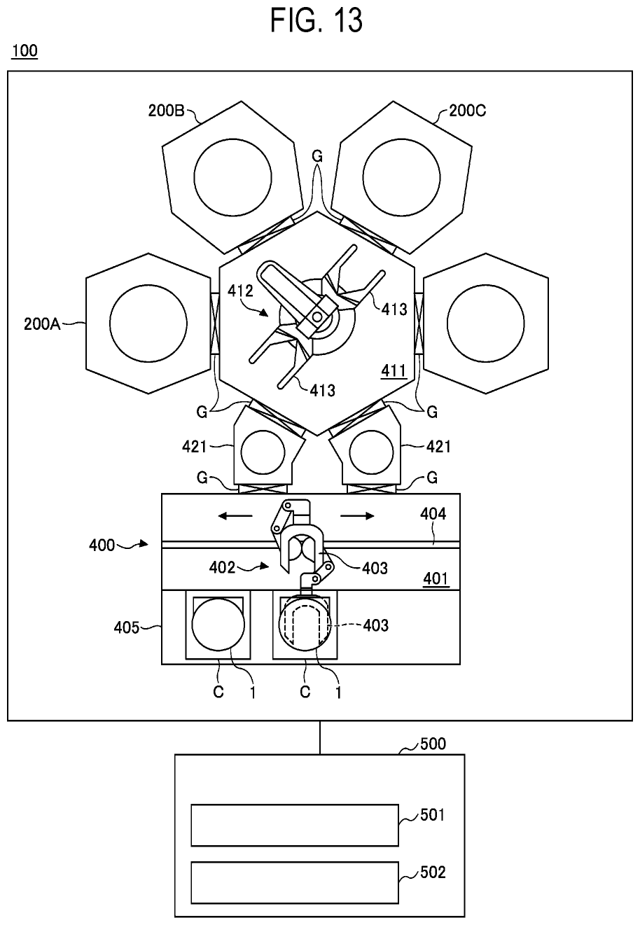

Next, a film forming apparatus 100 for carrying out the above-mentioned film forming method will be described with reference to FIG. 13. The film forming apparatus 100 carries out the film forming method shown in FIG. 3, for example. The film forming apparatus 100 may carry out the film forming method shown in FIG. 7 or FIG. 11. As shown in FIG. 13, the film forming apparatus 100 includes a first processing part 200A, a second processing part 200B, a third processing part 200C, a transfer part 400, and a control circuit 500. The first processing part 200A carries out, for example, step S202 in FIG. 3. The second processing part 200B carries out, for example, steps S203 to S204 in FIG. 3. The third processing part 200C carries out, for example, step S205 in FIG. 3. The processing from step S206 onwards is performed outside the film forming apparatus 100, but may also be performed inside the film forming apparatus 100. The first processing part 200A, the second processing part 200B, and the third processing part 200C may have the same structure or may have different structures. It is also possible to perform all of steps S202 to S205 in FIG. 3 only with the first processing part 200A. The transfer part 400 transfers the substrate 1 to the first processing part 200A, the second processing part 200B, and the third processing part 200C. The control circuit 500 controls the first processing part 200A, the second processing part 200B, the third processing part 200C, and the transfer part 400.

The transfer part 400 includes a first transfer chamber 401 and a first transfer mechanism

402. The internal atmosphere of the first transfer chamber 401 is an air atmosphere. The first transfer mechanism 402 is installed inside the first transfer chamber 401. A load port 405 is installed on a wall surface of the first transfer chamber 401. A carrier C in which a substrate 1 is accommodated is attached to the load port 405. For example, a FOUP (Front Opening Unified Pod) or the like may be used as the carrier C. The first transfer mechanism 402 includes an arm 403 that holds the substrate 1 and travels along a rail 404. The rail 404 extends in the arrangement direction of the carrier C.

The transfer part 400 also includes a second transfer chamber 411 and a second transfer mechanism 412. The internal atmosphere of the second transfer chamber 411 is a vacuum atmosphere. The second transfer mechanism 412 is installed inside the second transfer chamber 411. The second transfer mechanism 412 includes an arm 413 that holds the substrate 1. The arm 413 is arranged to be movable in the vertical and horizontal directions and rotatable about a vertical axis. The first processing part 200A, the second processing part 200B, and the third processing part 200C are connected to the second transfer chamber 411 via different gate valves G.

Further, the transfer part 400 includes a load lock chamber 421 between the first transfer chamber 401 and the second transfer chamber 411. The internal atmosphere of the load lock chamber 421 may be switched between a vacuum atmosphere and an air atmosphere by a pressure regulation mechanism (not shown). This allows the inside of the second transfer chamber 411 to be constantly maintained in a vacuum atmosphere. In addition, it is possible to prevent a gas from flowing from the first transfer chamber 401 into the second transfer chamber 411. Gate valves G are provided between the first transfer chamber 401 and the load lock chamber 421, and between the second transfer chamber 411 and the load lock chamber 421.

The control circuit 500 is, for example, a computer, and includes an arithmetic part 501 such as a CPU (Central Processing Unit) or the like and a memory part 502 such as a memory or the like. The memory part 502 stores programs that control various processes executed in the film forming apparatus 100. The control circuit 500 controls the operation of the film forming apparatus 100 by causing the arithmetic part 501 to execute the programs stored in the memory part 502. The control circuit 500 controls the first processing part 200A, the second processing part 200B, the third processing part 200C, and the transfer part 400 to carry out the above-mentioned film forming method.

The control circuit 500 includes an electronic circuit such as a CPU, an FPGA (Field Programmable Gate Array) or an ASIC (Application Specific Integrated Circuit), and performs the various control operations described in this specification by executing instruction codes stored in a memory or by using a circuit designed for a specific application.

Next, the operation of the film forming apparatus 100 will be described. First, the first transfer mechanism 402 takes out the substrate 1 from the carrier C, transfers the taken-out substrate 1 to the load lock chamber 421, and retreats from the load lock chamber 421. Next, the internal atmosphere of the load lock chamber 421 is switched from the air atmosphere to a vacuum atmosphere. Thereafter, the second transfer mechanism 412 takes out the substrate 1 from the load lock chamber 421, and transfers the taken-out substrate 1 to the first processing part 200A.

Next, the first processing part 200A performs step S202. Thereafter, the second transfer mechanism 412 takes out the substrate 1 from the first processing part 200A and transfers the taken-out substrate 1 to the second processing part 200B. During this time, the atmosphere around the substrate 1 may be maintained as a vacuum atmosphere, which makes it possible to suppress unintended oxidation of the substrate 1.

Next, the second processing part 200B performs steps S203 to S204. Thereafter, the second transfer mechanism 412 takes out the substrate 1 from the second processing part 200B and transfers the taken-out substrate 1 to the third processing part 200C. During this time, the atmosphere around the substrate 1 may be maintained as a vacuum atmosphere, which makes it possible to suppress unintended oxidation of the substrate 1.

Next, the third processing part 200C performs step S205. Thereafter, the second transfer mechanism 412 takes out the substrate 1 from the third processing part 200C, transfers the taken-out substrate 1 to the load lock chamber 421, and retreats from the load lock chamber 421. The internal atmosphere of the load lock chamber 421 is then switched from the vacuum atmosphere to an air atmosphere. Thereafter, the first transfer mechanism 402 takes out the substrate 1 from the load lock chamber 421, and stores the taken-out substrate 1 in the carrier C. Then, the processing of the substrate 1 is completed.

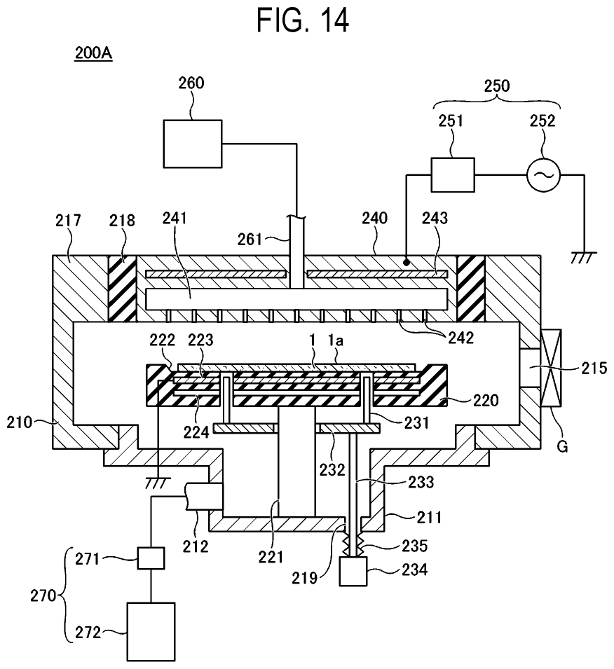

Next, the first processing part 200A will be described with reference to FIG. 14. The second processing part 200B and the third processing part 200C are configured similarly to the first processing part 200A, and thus, the illustration and description will be omitted.

The first processing part 200A includes a substantially cylindrical airtight processing container 210. An exhaust chamber 211 is provided at the center of the bottom wall of the processing container 210. The exhaust chamber 211 has, for example, a substantially cylindrical shape that protrudes downward. An exhaust pipe 212 is connected to the exhaust chamber 211, for example, at a side surface of the exhaust chamber 211.

An exhaust source 272 is connected to the exhaust pipe 212 via a pressure controller 271. The pressure controller 271 includes a pressure regulation valve such as a butterfly valve or the like. The exhaust pipe 212 is configured so that the inside of the processing container 210 may be depressurized by the exhaust source 272. The pressure controller 271 and the exhaust source 272 constitute a gas exhaust mechanism 270 that exhausts a gas from the inside of the processing container 210.

A transfer port 215 is provided on the side surface of the processing container 210. The transfer port 215 is opened and closed by a gate valve G. The substrate 1 is transferred between the processing container 210 and the second transfer chamber 411 (see FIG. 13) via the transfer port 215.

A stage 220, which is a holder for holding the substrate 1, is provided in the processing container 210. The stage 220 holds the substrate 1 horizontally with the substrate surface 1a facing upward. The stage 220 is formed in a substantially circular shape in a plan view, and is supported by a support member 221. A substantially circular recess 222 for holding the substrate 1 having a diameter of, for example, 300 mm is formed on the surface of the stage 220. The recess 222 has an inner diameter slightly larger than the diameter of the substrate 1. The depth of the recess 222 is set to be, for example, substantially the same as a thickness of the substrate 1. The stage 220 is formed of a ceramic material such as aluminum nitride (AlN) or the like. The stage 220 may also be formed of a metallic material such as nickel (Ni) or the like. Instead of the recess 222, a guide ring for guiding the substrate 1 may be provided on the peripheral edge portion of the surface of the stage 220.

A grounded lower electrode 223 is embedded in the stage 220. A heating mechanism 224 is embedded below the lower electrode 223. The heating mechanism 224 heats the substrate 1 held on the stage 220 to a set temperature by being supplied with electric power from a power supplier (not shown) based on a control signal from the control circuit 500 (see FIG. 13). When the entire stage 220 is made of a metal, the entire stage 220 functions as a lower electrode. Therefore, the lower electrode 223 does not need to be embedded in the stage 220.

The stage 220 is provided with a plurality of (e.g., three) lift pins 231 for holding and lifting the substrate 1 held on the stage 220. The material of the lift pins 231 may be, for example, ceramics such as alumina (Al₂O₃) or quartz. The lower ends of the lift pins 231 are attached to a support plate 232. The support plate 232 is connected to a lifting mechanism 234 provided outside the processing container 210 via a lifting shaft 233.

The lifting mechanism 234 is installed, for example, at the bottom of the exhaust chamber 211. A bellows 235 is installed between the lifting mechanism 234 and an opening 219 for the lifting shaft 233 formed at the bottom surface of the exhaust chamber 211. The support plate 232 may be shaped so that it may be raised and lowered without interfering with the support member 221 of the stage 220. The lifting pins 231 are configured to be freely raised and lowered by the lifting mechanism 234 between above the surface of the stage 220 and below the surface of the stage 220.

A gas supplier 240 is provided at the ceiling wall 217 of the processing container 210 via an insulating member 218. The gas supplier 240 forms an upper electrode and faces the lower electrode 223. A radio-frequency power source 252 is connected to the gas supplier 240 via a matcher 251. By supplying radio-frequency power of 450 kHz to 100 MHz from the radio-frequency power source 252 to the upper electrode (gas supplier 240), a radio-frequency electric field is generated between the upper electrode (gas supplier 240) and the lower electrode 223, thereby generating capacitively coupled plasma. A plasma generator 250 that generates plasma includes the matcher 251 and the radio-frequency power source 252. The plasma generator 250 may generate not only the capacitively coupled plasma, but also other plasma such as inductively coupled plasma. In a process that does not generate plasma, the gas supplier 240 does not need to form an upper electrode, and the lower electrode 223 is also not needed.

The gas supplier 240 includes a hollow gas supply chamber 241. A number of holes 242 for dispersing and supplying a processing gas into the processing container 210 are arranged, for example, uniformly on the bottom surface of the gas supply chamber 241. A heating mechanism 243 is embedded in the gas supplier 240, for example, above the gas supply chamber 241. The heating mechanism 243 is heated to a set temperature by being supplied with electric power from a power supplier (not shown) based on a control signal from the control circuit 500.

A gas supply mechanism 260 is connected to the gas supply chamber 241 via a gas supply path 261. The gas supply mechanism 260 supplies gases used in the film forming method to the gas supply chamber 241 via the gas supply path 261. Although not shown, the gas supply mechanism 260 includes an individual pipe for each type of gas, an opening/closing valve installed in the middle of the individual pipe, and a flow rate controller installed in the middle of the individual pipe. When the opening/closing valve opens the individual pipe, a gas is supplied from the supply source to the gas supply path 261. The supply amount of the gas is controlled by the flow rate controller. On the other hand, when the opening/closing valve closes the individual pipe, the supply of the gas from the supply source to the gas supply path 261 is stopped.

Although the embodiments of the film forming method and the film forming apparatus according to the present disclosure have been described above, the present disclosure is not limited to the above-described embodiments. Various changes, modifications, substitutions, additions, deletions, and combinations may be made within the scope recited in the claims. It goes without saying that these also fall within the technical scope of the present disclosure.

According to the present disclosure in some embodiments, it is possible to reduce electrical resistance between a first metal film and a second metal film and to improve adhesiveness between a first insulating film and the second metal film.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method, comprising, sequentially performing:
preparing a substrate having a first metal film and a first insulating film formed in different regions of a surface of the substrate;
forming a first self-assembled monolayer on a surface of the first metal film selectively with respect to a surface of the first insulating film;
forming a first bonding film on both the surface of the first insulating film and a surface of the first self-assembled monolayer using a first molecular bonding agent;
removing the first self-assembled monolayer to remove a portion of the first bonding film in contact with the surface of the first self-assembled monolayer; and
forming a second metal film on a surface of a remaining portion of the first metal film and the surface of the first insulating film,
wherein the first molecular bonding agent is an organic compound having a first functional group and a second functional group in one molecule,
wherein the first functional group is more likely to bond to the first insulating film than the second functional group, and
wherein the second functional group is more likely to bond to the second metal film than the first functional group.

2. The method of claim 1, wherein the removing the first self-assembled monolayer includes heating the first self-assembled monolayer.

3. The method of claim 2, wherein a 1% weight loss temperature of the first self-assembled monolayer is lower than a 1% weight loss temperature of the first bonding film.

4. The method of claim 1, wherein the removing the first self-assembled monolayer includes supplying acetic acid to the first self-assembled monolayer.

5. The method of claim 1, wherein a material of the first self-assembled monolayer is an organic compound containing a thiol group.

6. The method of claim 1, wherein the first metal film and the second metal film contain Ru.

7. The method of claim 1, wherein the substrate has a recess on the surface of the substrate,
wherein a bottom surface of the recess includes the surface of the first metal film, and
wherein a side surface of the recess includes the surface of the first insulating film.

8. The method of claim 1, wherein the first functional group includes at least one of a silanol group or a group that generates the silanol group by hydrolysis reaction.

9. The method of claim 1, wherein the second functional group includes at least one of an amino group, an azide group, a mercapto group, an isocyanate group, a ureido group, or an epoxy group.

10. The method of claim 1, wherein the first molecular bonding agent includes a triazine between the first functional group and the second functional group.

11. The method of claim 1, further comprising, sequentially performing:
polishing the second metal film to align a surface of the second metal film and the surface of the first insulating film in the same plane;
forming a second self-assembled monolayer on the surface of the second metal film selectively with respect to the surface of the first insulating film;
forming a second bonding film on both the surface of the first insulating film and a surface of the second self-assembled monolayer using a second molecular bonding agent;
removing the second self-assembled monolayer to remove a portion of the second bonding film in contact with the surface of the second self-assembled monolayer; and
forming a third metal film on a surface of a remaining portion of the second bonding film and the surface of the second metal film,
wherein the second molecular bonding agent is an organic compound having a third functional group and a fourth functional group in one molecule,
wherein the third functional group is more likely to bond to the first insulating film than the fourth functional group, and
wherein the fourth functional group is more likely to bond to the third metal film than the third functional group.

12. A film forming apparatus, comprising:
a processing container;
a holder configured to hold a substrate inside the processing container;
a gas supply mechanism configured to supply a gas into the processing container;
a gas exhaust mechanism configured to exhaust a gas from the processing container;
a transfer mechanism configured to load and unload the substrate into and from the processing container; and
a control circuit configured to control the gas supply mechanism, the gas exhaust mechanism, and the transfer mechanism to carry out the film forming method of claim 1.
